(19) United States
(12) Patent Application Publication
(10) Pub. No.: US 2018/0152162 A1
(43) Pub. Date: May 31, 2018

(54) Microcontroller Operated Backup Alarm Device

(71) Applicant: Ramasamy Krishnaswamy, Coimbatore (IN)

(72) Inventor: Ramasamy Krishnaswamy, Coimbatore (IN)

(21) Appl. No.: 15/361,725

(22) Filed: Nov. 28, 2016

(51) Int. Cl. H03G 3/32; H02H 9/04; G08B 3/10; H04R 3/00; H04R 29/00; B60Q 5/00

(52) U.S. Cl. CPC H03G 3/32; H02H 9/045; G08B 3/10; H04R 2400/01; H04R 29/001; B60Q 5/005; H04R 3/007

(57) ABSTRACT

The invention consist of a microcontroller operated electronic Backup Alarm Device for use in vehicles, especially in trucks, buses, heavy vehicles, earthmovers, mini trucks, and material handling moveable vehicles. The inventive feature is the use of a electronically powered programmed microcontroller and a speaker driver circuit, current sensing circuit and an amplifier, on a Printed Circuit Board (PCB) Assembly suitably connected to a speaker, where the speaker has a dual function of acting both as a mike and as a speaker.

### FIELD OF INVENTION

The invention pertains to a breakthrough achieved in the field of production of Backup Alarm devices by use of a microcontroller and speaker device circuit in place of Digital Internal Circuits and operational amplifiers, thereby eliminating the problem of echo during the functioning of the device and also substantially bringing down the production cost of the device.

### PRIOR ART

Prior art backup alarms include those described in U.S. Pat. Nos. 3,173,136 (Atkinson), 2,517,629 (Buys etal), 2,462,532 (Morris), 2,431,117 (Hadley) and 4,603,317 (Samuel and Ronald).

Atkinson shows a backup horn wherein the volume of the horn is automatically variable depending upon the background noise level, and wherein the horn itself is used alternately as a horn and a microphone for determining the background noise. Buys etal teaches a volume control system for sound reproduction in railway yards utilizing two micro phones separate from at least one loudspeaker.

Morris describes a sound system which compensates for variable noise levels, also utilizing a microphone separate from one or more loudspeakers. Hadley provides a backup warning device which emits an intermittent signal at a frequency proportional to the speed of a rearwardly moving vehicle.

Samuel and Ronald describes the sound pressure level of electrically operated backup alarm delivering 10 dBA greater than the abient sound pressure level at all the times automatically when it is working.

### SUMMARY OF INVENTION

The invention consist of a microcontroller operated electronic Backup Alarm Device for use in vehicles, especially in trucks, buses, heavy vehicles, earthmovers, mini trucks, and material handling moveable vehicles. The inventive feature is the use of a electronically powered programmed microcontroller and a speaker driver circuit, current sensing circuit, and an amplifier, on a Printed Circuit Board (PCB) Assembly suitably connected to a speaker, where the speaker has a dual function of acting both as a mike and as a speaker.

### BRIEF DESCRIPTION OF THE DRAWINGS

FIG. 1 is a block diagram of an electronically operated Backup Alarm device.

FIG. 2 is a block diagram of a PCB assembly.

FIG. 3 is a schematic diagram.

FIG. 4 is a connection diagram.

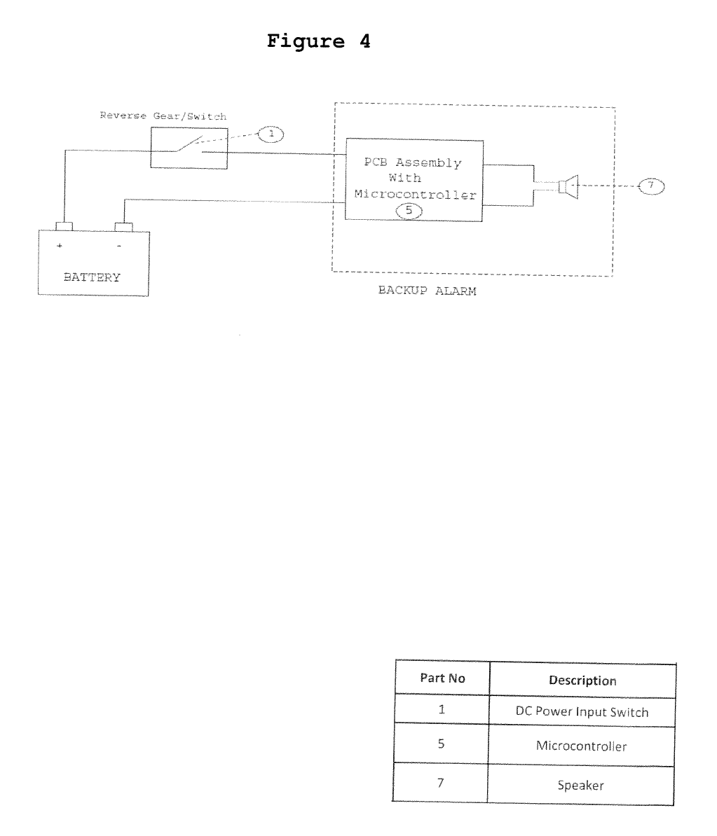

FIG. 5 is a waveform.

FIG. 6 is a functional graph.

### DESCRIPTION OF THE INVENTION

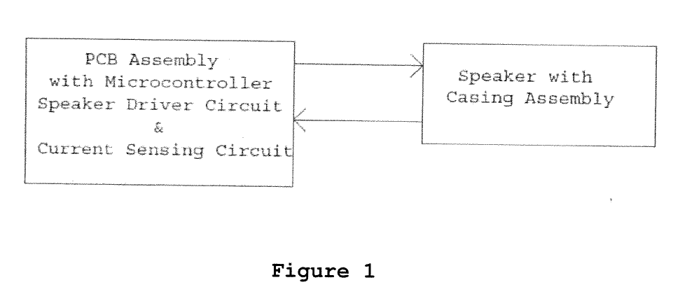

The invention as in FIG. 1 is an electronically operated Backup Alarm device for use in automobiles, in particular trucks, buses, heavy vehicles, earthmovers, mini trucks, and material handling moveable vehicles. The main inventive feature of the invention as in FIG. 1 is the use of a microcontroller with speaker driver circuit and current sensing circuit to perform the sensing and signaling of the speaker for purpose of generating the alarm.

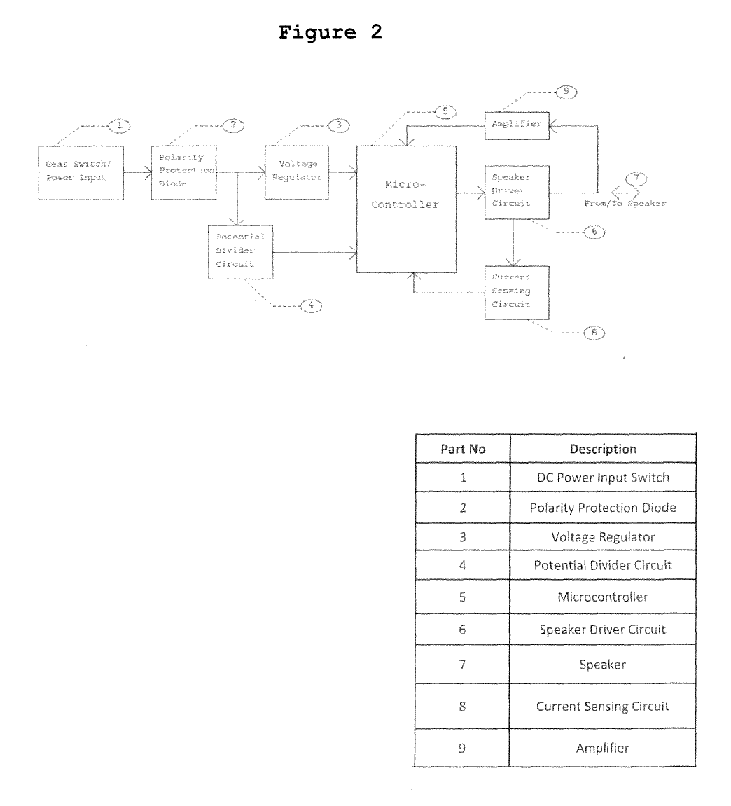

The invention is as described in FIG. 2 The microcontroller (5) is a computer processing unit connected to a speaker (7) through a speaker driver circuit (6). The speaker driver circuit is also connected to a current sensing circuit (8) which in turn is again connected to the Microcontroller (5). That apart, the speaker is connected to an amplifier (9) which is in turn connected to the microcontroller. The speaker performs a dual function of receiving the ambient noise and also delivering the sound output.

The microcontroller is powered by a D.C power source (1) through a Polarity Protection Diode (2) and a voltage regulator (3). A potential divider circuit (4) is connected in between the polarity protection diode and voltage regulator on one end, and the Microcontroller on the other end. It does a voltage sensing function by sensing the input voltage fed to the Microcontroller. The power source is activated when the gear lever is engaged in the reverse mode.

Further, the speaker driver circuit connected to the microcontroller through a sensing circuit acts as a preventive mechanism to switch off the speaker in case of short circuit or excess current supply to the speaker.

### WORKING OF THE INVENTION

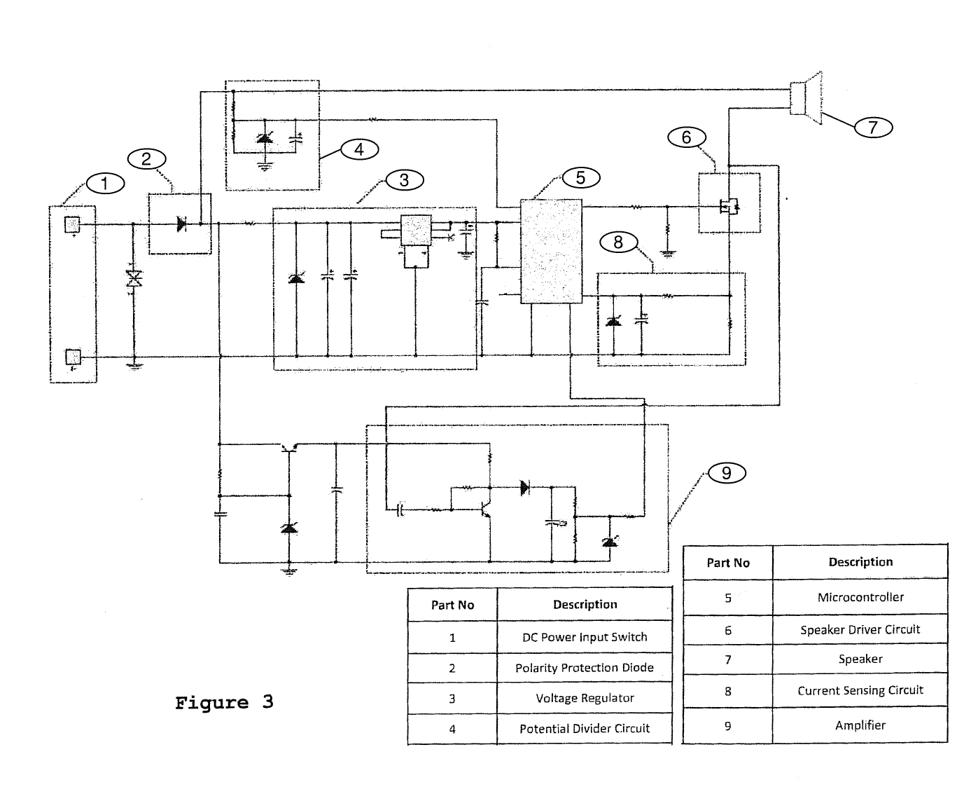

The working of the invention is as illustrated in FIG. 3. Switching on the power supply (1) by the appropriate movement of the gear lever in reverse mode activates the device. Where upon the speaker senses the ambient noise in the environment and sends the signal to the microcontroller through the amplifier.

The microcontroller (5) is programmed to various sound pressure level bands depending upon the nature and requirement of use.

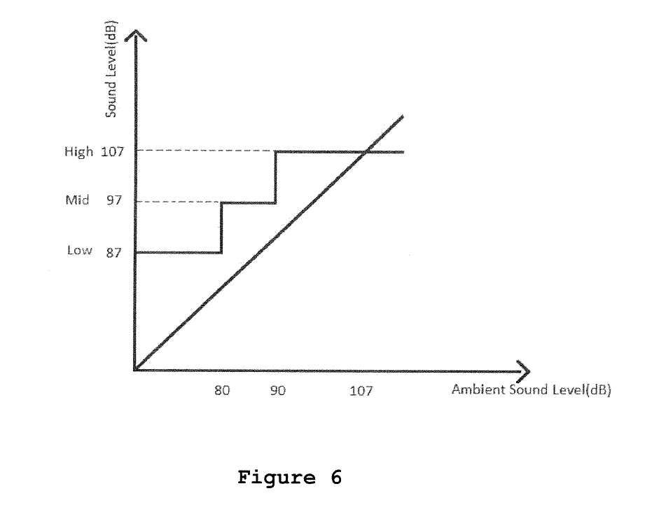

As illustrated in FIG. 6, in a preferred embodiment of the invention there are three sound pressure level (SPL) bands i.e., low, medium and high.

The technical advancement and main inventive features of the invention lies in three main aspects namely;
a) One time first sensing,
b) Maintaining the SPL band and the output volume through the speaker throughout a particular operation of the device and
c) Because of this the SPL band output remains constant, at one particularly selected level during one operation, irrespective of the change in ambient noise.

Eg.1: If the ambient sound level is 80 dB then the SPL band is chosen as 87 dB (FIG. 6), as per the programming of the Microcontroller. In other words for an ambient sound level from zero to 80 dB the SPL is maintained at 87 dB. Further, even if there is a change in the ambient sound level after the device has been switched on the SPL band output does not vary but remains fixed to what was initially sensed when the device is switched on for one operation.

Similarly, the above applies mutatis mutatis to the mid and high SPL bands as illustrated in FIG. 6.

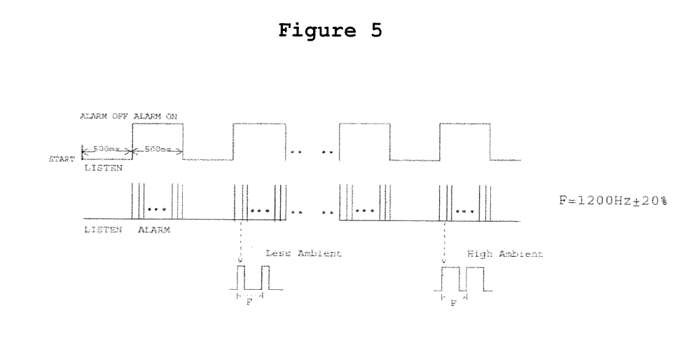

The amplifier (9) amplifies the input signal received from the speaker, which acts as a mike and sends it to the microcontroller for further processing. Depending upon the strength of the input signal received, the microcontroller based upon its program, generates a Pulse Width Modulated (PWM) signal of wave form as in FIG. 5 and sends it to the Speaker Driver Circuit (6). This signal instructs the speaker circuit to generate the output sound wave of particular amplitude as instructed by the microcontroller, which is intern sent to the speaker for output sound generation.

The wave form is as illustrated in FIG. 5. Each wave consists of two components namely, an, “on period” and an “off period”, each lasting for a fixed time period. The most preferred embodiment is 0.5 seconds. When the device is switched on the ambient noise sensed by the speaker acting as mike is fed to the microcontroller through the amplifier. Based on the input the microcontroller (5) generates an output signal to be fed to the speaker driver circuit (6). The microcontroller is so programmed that, the output signal generated by it remains fixed to the one initially generated when the device is switched on throughout the performance of one operation. This is termed as “one time initial sensing”. Therefore, the microcontroller does not vary the output even if there is a variation in the ambient sound level during a particular operation.

The pulse width of the signal is low when the ambient noise is low and vice versa, as illustrated FIG. 5.

Therefore, the prime inventive feature of the invention is the microcontroller which does only one initial sensing and signal generating function through the entire functioning of the device. This is done at the initial stage, immediately when the device is switched on. The signal from the microcontroller (5) is sent to the Speaker Device Circuit (6) which maintains consistency so that the output noise produced is constant giving no room for variations due to echo. This is one of the main advantage of the invention over existing prior art.

This output sound signal generated by the speaker device circuit is duly amplified herein and sent to the speaker for purpose of producing the alarm as output.

Further, the speaker driver circuit (6) is connected to a current sensing circuit (8) which in turn is connected to the microcontroller. In case of any short circuit or over current in the speaker either at the time of reception or at the time of transmission the same is reflected by a sudden jump in the current in the speaker driver circuit (6) which is sensed by the sensing circuit, which then immediately sends a signal to the microcontroller which in turn switches off the entire circuit thereby preventing electric damage to the device. Therefore, the current sensing circuit (8) acts as a safety device thus enhancing the life of the device and preventing it from damage due to electrical fluctuations. This is yet another inventive feature of the said device. Therefore, enhancing the life of the device and achieving reduced cost of production attributes great economic significance to the invented device.

The microcontroller gets input power from a power source through a polarity protection diode (2) and a voltage regulator (3) which regulates the voltage within operational levels thus cutting off excess voltage and to maintain the polarity of the input power respectively so as to prevent damage to the microcontroller, or voltage fluctuation or polarity reversal.

Further, there is a potential divider circuit (4) connected in between the polarity protection diode (2) and the voltage regulator (3) at one end and the microcontroller (5) on the other. This does the function as already mentioned.

The main advantage of the invention is the use of microcontroller, Speaker Driver Circuit and Current Sensing Circuit in place of the conventional digital ICs and operational amplifiers thus reducing the production cost.

Therefore the invention is highly cost effective.

Further the problem of output sound increasing because of echo when used in closed drive way is totally eliminated. Further there no limitation on the number of sound pressure bands. This increases the range of output sound produced.

Still further, the “one time initial sensing aspect” makes this invention highly advantageous for use in closed or narrow drive ways where the problem of echo is very high.

The use of the current sensing circuit as a safety mechanism enhances the life of the device thus increasing product life, combined with less production cost and achieving the required utility, attributes great economic significance to the invention.

1. An electronically operated backup alarm device comprising
a microcontroller,
a dual functioning speaker with amplifier,
a speaker driver circuit, and
a current sensing circuit,
wherein all of the speaker, speaker driver circuit, and current sensing circuit are suitably connected to the microcontroller, to perform one time fixed sensing and to maintain an SPL band and an output volume through the speaker throughout a particular operation of the backup alarm device so that the SPL band output remains constant, at one particularly selected level during one operation, irrespective of an input voltage.

2. The electronically operated backup alarm device of claim 1, wherein the microcontroller is a processing unit which is connected to the speaker through an amplifier to receive signals from the speaker, as input, and also connected through a speaker device circuit to the speaker to deliver audible output.

3. The electronically operated backup alarm device of claim 2, wherein the microcontroller performs only one initial sensing when the backup alarm device is switched on.

4. The electronically operated backup alarm device of claim 1, wherein the microcontroller has “n” number of input bands, and corresponding outputs.

5. The electronically operated backup alarm device of claim 4, wherein the amplitude of input signal from the amplifer is converted by the microcontroller as programmed for delivery as output.

6. The electronically operated backup alarm device of claim 1, wherein the speaker driver circuit is connected to the current sensing circuit which is in turn connected to the microcontroller, and the current sensing circuit acts as a safety device in protecting the speaker from damage due to short circuit or high current in the speaker.
